(19) United States
(12) Patent Application Publication
(10) Pub. No.: US 2015/0094965 A1
(43) Pub. Date: Apr. 2, 2015

(54) Electrical Power Grid Monitoring Apparatus, Articles of Manufacture, and Methods of Monitoring Equipment of an Electrical Power Grid

(71) Applicant: Battelle Memorial Institute, Richland, WA (US)

(72) Inventors: Kevin P. Schneider, Seattle, WA (US); Mark J. Rice, Kennewick, WA (US); Tess L. Williams, Seattle, WA (US); Beau B. Van Kirk, III, Seattle, WA (US)

(73) Assignee: Battelle Memorial Institute, Richland, WA (US)

(21) Appl. No.: 14/042,414

(22) Filed: Sep. 30, 2013

(51) Int. Cl. G01R 31/02; G01R 21/133

(52) U.S. Cl. CPC G01R 31/02; G01R 21/133
USPC 702/58

(57) ABSTRACT

Electrical power grid monitoring apparatus, articles of manufacture, and methods of monitoring equipment of an electrical power grid are described. According to one aspect, an electrical power grid monitoring apparatus includes a communications interface configured to access electrical data indicative of electrical energy received at a plurality of consumer locations from an electrical power grid at a plurality of moments in time, the consumer locations being coupled with one or more unbalanced single phase feeders of a distribution system of an electrical power grid and which individually comprise a plurality of components configured to conduct the electrical energy from at least one electrical energy source to the consumer locations, and processing circuitry coupled with the communications interface and configured to use the electrical data to estimate a state of the electrical power grid and to identify one of the components as being in a potentially degraded state using the estimation of the state of the electrical power grid.

### STATEMENT AS TO RIGHTS TO INVENTIONS MADE UNDER FEDERALLY-SPONSORED RESEARCH AND DEVELOPMENT

This invention was made with Government support under Contract DE-AC0576RLO1830 awarded by the U.S. Department of Energy. The Government has certain rights in the invention.

### TECHNICAL FIELD

This disclosure relates to electrical power grid monitoring apparatus, articles of manufacture, and methods of monitoring equipment of an electrical power grid.

### BACKGROUND OF THE DISCLOSURE

A significant challenge to operating electric distribution systems is the lack of a direct monitoring capability. Equipment is often deployed and left unattended for multiple decades and operators have no indication of the equipment condition. This is especially true of secondary service transformers and underground cables. After these components are deployed, they are often left in operation until they fail, which results in unplanned outages for end-use customers. Because of the large number of secondary service transformers and underground cables, it is not practical to install monitoring equipment or to perform manual inspections. To address these limitations, utilities often over-build their systems to provide additional safety margins, which result in higher capital construction costs. Even with these increased safety margins it is not uncommon for failures of secondary service transformers and/or underground cables to result in customer outages.

At least some of the aspects of the disclosure are directed towards methods and apparatus which monitor equipment of an electrical power grid. Additional aspects are discussed below.

### BRIEF DESCRIPTION OF THE DRAWINGS

Example embodiments of the disclosure are described below with reference to the following accompanying drawings.

FIG. 1 is a functional block diagram of an electrical power system according to one embodiment.

FIG. 2 is a functional block diagram of a computing system according to one embodiment.

FIG. 3 is a flow chart of a method of monitoring equipment of an electrical power grid according to one embodiment.

FIG. 4 is a map showing how FIGS. 4A and 4B are to be assembled. Once assembled, FIGS. 4A and 4B are a flow chart of a method of monitoring equipment of an electrical power grid according to one embodiment.

FIG. 5 is a schematic representation of a distribution feeder according to one embodiment.

FIG. 6 is a flow chart of data collection and processing flow according to one embodiment.

FIG. 7 is a graphical representation of the effect of parameter error on a parameter on normalized measurement residuals according to one embodiment.

FIG. 8 is a graphical representation of the effect of parameter error on a parameter on normalized Lagrangian according to one embodiment.

FIG. 9 is a graphical representation of estimated error on a parameter at one snapshot according to one embodiment.

FIG. 10 is a graphical representation of estimated error on multi-parameters at two snapshots according to one embodiment.

FIG. 11 is a graphical representation of estimated error on a parameter at one snapshot according to one embodiment.

FIG. 12 is a graphical representation of estimated values of parameters for plural days according to one embodiment.

FIG. 13 is a graphical representation of estimated errors on parameters for plural days according to one embodiment.

FIG. 14 is a graphical representation of estimated values of a parameter according to one embodiment.

FIG. 15 is a graphical representation of estimated error on a parameter according to one embodiment.

FIG. 16 is a graphical representation of estimated shunt capacitance as a function of day according to one embodiment.

FIG. 17 is a graphical representation of estimated error of line resistivity parameters of a link according to one embodiment.

### DETAILED DESCRIPTION OF THE DISCLOSURE

This disclosure is submitted in furtherance of the constitutional purposes of the U.S. Patent Laws “to promote the progress of science and useful arts” (Article 1, Section 8).

As described below, some embodiments of the disclosure use electrical data regarding electrical energy conducted within an electrical power grid to determine the condition of equipment of the electrical power grid, which may be referred to as components, such as transformers and underground cables. One embodiment utilizes electrical data that already exists (e.g., Automatic Meter Information (AMI)) and which can processed over long time periods to determine the health of equipment. In one aspect, an informed condition based maintenance approach may be formulated that will reduce maintenance cost by reducing unnecessary replacements and reduce the number of unplanned outages due to equipment failure.

While AMI measurements do not directly measure affected equipment of interest, some embodiments use state and parameter estimation methods, in conjunction with models of expected equipment behaviors, to determine if the equipment is deteriorating in an unexpected manner. At least some of the embodiments are designed to capture failure modes that result from overloads or overheating condition that slowly degrade the equipment, and can lead to failures

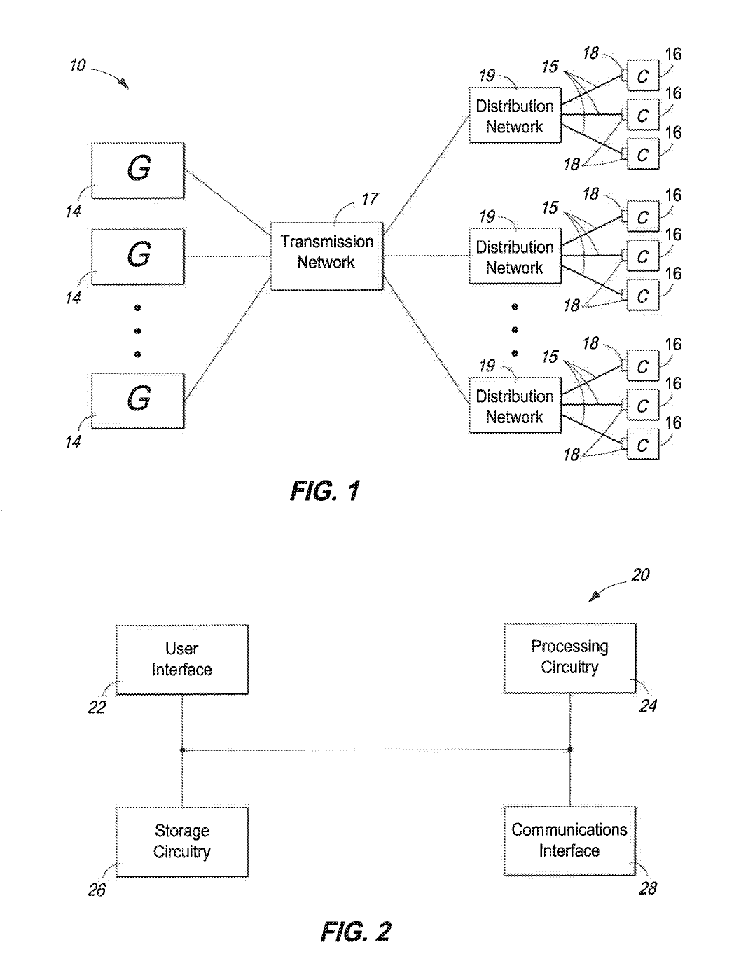

Referring to FIG. 1, one illustrative example of an electrical power system 10 is shown. Electrical power systems connect power producers and consumers through a complex network of transmission and distribution lines. Power producers use a variety of generator technologies, from coal to natural gas to nuclear and hydro, to create electricity. There are hundreds of large generation facilities spread across the United States, with many smaller facilities. Power is transferred from the generation facility to the transmission network, which moves it to where it is needed. The transmission network is comprised of high voltage lines that connect the generators to distribution points. The network is designed with redundancy, which allows power to flow to most locations even when there is a break in the line or a generator goes down unexpectedly. At specific distribution points, the voltage is decreased and then transferred to the consumer.

In the depicted example, an electrical power system 10 includes a plurality of electrical sources 14 (e.g., generators, renewable energy sources, etc.) and a plurality of electrical loads or consumers 16 (e.g., residences, businesses, etc.) coupled with an electrical power grid. The illustrated arrangement of the electrical power grid includes a transmission network 17 and a plurality of distribution networks 19 to conduct electrical energy from electrical sources 14 to consumers 16. The transmission network 17 may include balanced three phase high voltage conductors and individual distribution networks 19 may include unbalanced single phase branch or feeder connections 15 for providing lower voltage electrical energy to one or more consumers 16. Substations and transformers (not shown) may be used to provide electrical energy of appropriate voltages in the transmissions and distribution networks 17, 19. A plurality of consumers 16 may be connected with a single phase unbalanced connection 15. An individual single phase unbalanced connection 15 may include a plurality of components configured to conduct the electrical energy from at least one electrical energy source to the consumer locations.

The illustrated electrical power system 10 also includes a plurality of sensors 18 which monitor the electrical power system 10 including the flow of electrical energy within and/or with respect to the electrical power system 10. Sensors 18 may be individually configured to monitor electrical energy flowing within a respective conductor of the electrical power system 10 in one embodiment. In the specific embodiment of FIG. 1, sensors 18 may be deployed to monitor electrical energy received at respective locations of individual consumers 16 which may be houses, apartments, businesses, etc.

In one embodiment, sensors 18 are meters which may monitor and record variables or characteristics of electrical energy, such as the grid frequency, voltage, current, and phase angles at very high time resolution. In one more specific embodiment, the meters are AMI meters. In one embodiment, the sensors 18 record the variables or characteristics at a plurality of common moments in time with one another (e.g., AMI meters are time-synchronized with one another).

Referring to FIG. 2, one embodiment of a computing system 20 configured to implement processing and analysis operations with respect to the electrical power system 10 is shown. In the illustrated example embodiment, computing system 20 includes a user interface 22, processing circuitry 24, storage circuitry 26, and a communications interface 28. Other embodiments of computing system 20 are possible including more, less and/or alternative components.

User interface 22 is configured to interact with a user including conveying data to a user (e.g., displaying visual images, graphs, processing results, indications of potentially degraded or faulty equipment of the electrical power system, etc. for observation by the user) as well as receiving inputs from the user in one embodiment. User interface 22 is configured as a graphical user interface or command line interface in example embodiments.

In one embodiment, processing circuitry 24 is arranged to process and analyze data, control data access and storage, issue commands, and control other desired operations. Processing circuitry 24 may comprise circuitry configured to implement desired programming provided by appropriate computer-readable storage media in at least one embodiment. For example, the processing circuitry 24 may be implemented as one or more processor(s) and/or other structure configured to execute executable instructions including, for example, software and/or firmware instructions. A plurality of processors may operate in parallel in some distributed parallel processing implementations. Other example embodiments of processing circuitry 24 include hardware logic, PGA, FPGA, ASIC, state machines, and/or other structures alone or in combination with one or more processor(s). These examples of processing circuitry 24 are for illustration and other configurations are possible.

Storage circuitry 26 is configured to store programs such as executable code or instructions (e.g., software and/or firmware), electronic data, databases, a metadata repository, or other digital information and may include computer-readable storage media. A plurality of storage components may operate in parallel in some embodiments. At least some embodiments or aspects described herein may be implemented using programming stored within one or more computer-readable storage medium of storage circuitry 26 and configured to control appropriate processing circuitry 24.

The computer-readable storage medium may be embodied in one or more articles of manufacture which can contain, store, or maintain programming, data and/or digital information for use by or in connection with an instruction execution system including processing circuitry 24 in one embodiment. For example, computer-readable storage media may be non-transitory and include any one of physical media such as electronic, magnetic, optical, electromagnetic, infrared or semiconductor media. Some more specific examples of computer-readable storage media include, but are not limited to, a portable magnetic computer diskette, such as a floppy diskette, a zip disk, a hard drive, random access memory, read only memory, flash memory, cache memory, and/or other configurations capable of storing programming, data, or other digital information.

Communications interface 28 is arranged to implement communications of computing system 20 with respect to both internal and external devices while providing communication among components of the computing system 20. The interface 28 also supports access to external sensors and data sources, such as AMI meters, files containing AMI data and other internet based information. Communications interface 28 may be arranged to communicate information bi-directionally with respect to computing system 20. Communications interface 28 may be implemented as a network interface card (NIC), serial or parallel connection, USB port, Firewire interface, flash memory interface, or any other suitable arrangement for implementing communications with respect to computing system 20.

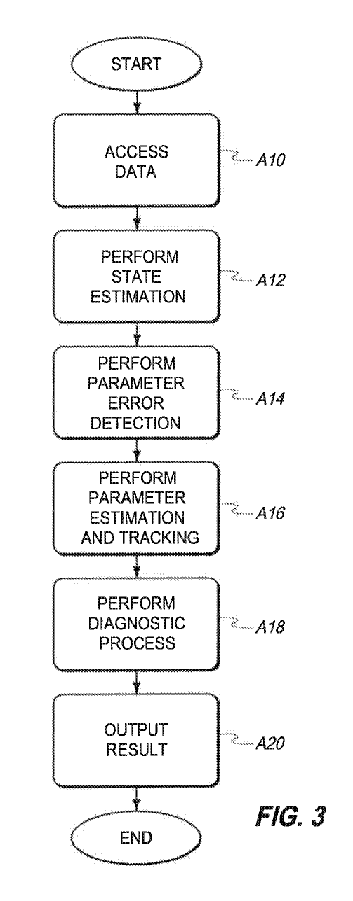

Referring to FIG. 3, one example method which may be executed by the computing system 20 implement processing and analysis operations with respect to the electrical power system 10 is shown. Other methods are possible including more, less and/or alternative acts. As discussed in detail below, the inputs to method are processed to provide an output list of transformers and underground cables that are flagged as having abnormal conditions which may warrant additional investigation, potential inspection, repair, or replacement.

At an act A10, data to be processed is accessed. In one embodiment, three classes of input data are accessed including plan data, operational data, and electrical data (which may be measured in one example).

The plan data may include a distribution feeder planning model which is a complete per phase model of a feeder (i.e., from a substation transformer to a secondary service transformer) which is normally maintained by a utility's planning department. This data includes the topology of the electrical power system as well as the type of equipment that is believed to be installed. These models also contain what the electrical parameters of equipment are expected to be. This data may be updated on a semi-annual or annual basis in illustrative examples.

The operational data may include data regarding an operational state of the distribution feeder. For example, this data may include the current operational status of equipment components, such as breakers, switches, and jumpers. This information may typically be obtained from a utility's operations group and are typically continuously updated.

Electrical data includes data regarding electrical energy conducted within the electrical power system. For example, electrical data includes data indicative of electrical energy received at a plurality of consumer locations from an electrical power grid at a plurality of common, synchronized moments in time. The electrical data may include values of one or more characteristics (e.g., voltage magnitude and angle) of the electrical energy received at the consumer locations. In more specific embodiment, this data may include AMI data and feeder head power flow data. In one embodiment, a continual flow of AMI data is normally collected by a utility at 5 to 15 minute intervals. Because the proposed method uses large periods of data in some embodiments, high speed communication is not necessary and the data can be continuously collected at infrequent intervals as once a day in one embodiment.

At an act A12, the analysis of the data is performed following the access of the data. An unbalanced three-phase state estimation of the system may be initially conducted during one analysis example. This may be performed since one or more of the sources of input data may contain sources of error. The described state estimation process determines a best fit estimate for the state variables of the system, the magnitude and phase angle of the voltage at each bus which may have multiple nodes, for example, phase a, phase b, and phase c. In one embodiment, the estimation of the state of the electrical power grid provides estimated values (e.g., best fit values) of electrical characteristics at a plurality of nodes of the electrical power grid in addition to the consumer locations and which may be utilized to perform diagnostics discussed in detail below.

In one embodiment, a standard Weighted Least Squares (WLS) power injection formulation for unbalanced per-phase distribution systems may be utilized as discussed in additional detail below. The output of this step is best fit estimated values for all of the state variables (e.g., characteristics of electrical energy, such as voltage and angle) and a set of measurement residuals which indicate the difference between each measurement and its respective derived best fit value for a respective characteristic of the electrical energy, for example, at a point of measurement of the data, such provided by an AMI meter in one embodiment, and its respective estimated value.

At an act A14, parameter error identification is performed wherein the measurement residuals are examined to determine if parameter errors exist. Parameter errors are detected by identifying multiple residuals with a high sensitivity to a common device parameter, (e.g., cable insulation, overhead line resistance, etc.) in one embodiment.

The output is a list of device parameters that are identified as being outside of the expected values indicated by the planning model in one embodiment. If a parameter is identified, it will be flagged for tracking. It is possible that multiple parameter errors will be identified, in which case multiple parameters will be flagged for tracking in one embodiment. The total number of parameters that can be monitored and tracked at a single time will depend on the observability of the system.

At an act A16, monitoring (e.g., estimation and tracking) of identified parameters is performed. More specifically, once a parameter, or set of parameters, has been flagged as potentially erroneous, an evaluation is performed to determine the best fit value for the parameter(s). Each time a set of new electrical data is collected, the best fit value is recalculated in one embodiment. In one embodiment, parameter estimation includes unbalanced per-phase distribution systems may be utilized as discussed in additional detail below.

At an act A18, a diagnostic process is performed. In one embodiment, the variation of parameters being tracked in act A16 are compared to known models to determine if their variation is within normal tolerances. If the parameter associated with the physical component is found to be changing in a way that is not consistent with component models or environmental trends, the component will be identified as of interest and in a potentially degraded state in one embodiment.

Consider underground cables as an example, which are prone to insulation failures. There are numerous diagnostic methods used to test power cables, and transformers, in order to ascertain deterioration and/or imminent potential for failure. The targeted characteristics of some of these tests may also be examined in online tests. For example, one of the more common tests for identifying cable failure is a dissipation factor or tan δ test which estimates the ratio of real to reactive impedance of the cable shunt impedance and which is discussed in M. Mashikian, “Preventive diagnostic testing of underground cables,” Conference and Exposition, 2001 IEEE/PES, 2001, and the teachings of which are incorporated herein by reference. While shunt components or elements are typically modeled in power flow as purely reactive, the model can be expanded to include complex shunt elements. Moreover, a trend in shunt capacitance alone may reproduce a similar trend as that seen in dissipation factor. Additional tests and targeted characteristics may be used in other embodiments. The amount of deviation from a known model to result in the respective component of the parameter being flagged for further investigation as a potentially degraded component may vary for different components in one embodiment.

At an act A20, the results of the diagnostics are output. The output may indicate one or more potentially degraded equipment which may be investigated further.

The discussion below provides additional details of analyzing equipment of an electrical power system in example embodiments.

Additional details regarding estimation of the state of the electrical power system are provided below. A process for implementing state estimation for a power system is discussed in F. C. Schweppe, “Power System Static-State Estimation, Part I: Exact Model,” IEEE Transactions on Power Apparatus and Systems, no. 1, pp. 120-125, 1970; F. Schweppe and D. Rom, “Power System Static-State Estimation, Part II: Approximate Model,” IEEE Transactions on Power Apparatus and Systems, vol. PAS-89, no. 1, pp. 125-130, January 1970; and F. Schweppe, “Power system static-state estimation, Part III: Implementation,” IEEE Transactions on Power Apparatus and Systems, no. 1, pp. 130-135, 1970, the teachings of each of which are incorporated herein by reference. Equation 3.1 shows an example formulation for a balanced state estimation solution.

x^{k+1}=x^{k}−[H^{T}(x^{k})R⁻¹H(x^{k})]⁻¹ [symbol] H^{T}(x^{k})R⁻¹[z−h(x^{k})] [symbol] (3.1)

where:

x^{k}: The state vector (phase angles and voltage magnitudes)

H^{T}: Jacobian of measurement equations with respect to state variables

R: Diagonal matrix of weighting values

h(x^{k}): Vector of measurement equations (functions of measured values)

z: Vector of measurements (line flows and voltage magnitudes) input to the state estimation problem.

Equation (3.1) is an iterative solution as is indicated by the superscript indexing of the state vector. The iteration continues until the difference between successive iterations is sufficiently small. This sufficiently small difference is referred to as the convergence criterion. Convergence criteria can vary but generally the quadratic convergence of the Weighted Lease Squares (WLS) method makes it clear when convergence has been achieved.

In one embodiment, the state estimation is performed for the individual unbalanced phases of the distribution networks of the electrical power system. In the traditional transmission state estimation, the measurements are one of six types including: Real power injections, Reactive power injections, Real power flows, Reactive power flows, Voltage magnitudes and Current magnitudes. In the balanced transmission application of state estimation, it is assumed that the system is balanced and that there is line transposition. Because of this, a single phase representation can be used to express each of the measured values as a function of the state variables. For example, the real power injection at bus i can be written as a function of the state variables V and θ, as shown in Equation (3.2). Equation (3.2) is the element of h(x^{k}) corresponding to the element of z for the measurement of Pᵢ. Each of the other 5 measurement types can be expressed in similar terms to Equation (3.2).

$${P}_{i} = {V}_{i} {\sum }_{k = 1}^{n} {V}_{k} [ {G}_{ik} cos {θ}_{ik} + {B}_{ik} sin {θ}_{ik} ] \qquad ( 3.2 )$$

Equation (3.2) may be expanded to include each of the individual phases in a distribution system {a, b, c} for use in distribution level state estimation in one embodiment and as discussed in C. W. Hansen and A. S. Debs, “Power System State Estimation Using Three-Phase Models,” IEEE Transactions on Power Systems, vol. 10, no. 2, pp. 818-824, 1995, the teachings of which are incorporated herein by reference. In this representation, the real power injection at bus i, for phase p, can be written as a function of the state variables V and θ, as shown in Equation (3.3). Both p and q represent the phase set {a, b, c}.

$${P}_{i}^{p} = {V}_{i}^{p} {\sum }_{k = 1}^{n} {\sum }_{q = 1}^{3} {V}_{k}^{q} [ {G}_{ik}^{pq} cos {θ}_{ik}^{pq} + {B}_{ik}^{pq} sin {θ}_{ik}^{pq} ] \qquad ( 3.3 )$$

Equation (3.3) shows the expansion from the traditional single phase, to the more general per-phase formulation, for the power injection at a single phase on a node. This same type of expansion can be made for the other five measurement types discussed above. However, for systems where AMI is utilized to provide the electrical data, generally only three measurement types are provided: Real power injections, Reactive power injections and Voltage magnitudes. By using the same formulation of Equation (3.1), but with the individual elements properly indexed across each of the three phases as shown in Equation (3.3), it is possible to perform an expanded three-phase distribution state estimation. This state estimation then gives the best fit estimate values for characteristics of the electrical energy in one embodiment (e.g., angle and voltage magnitude for each of the three phases at each node in the system). The best fit estimate may be utilized to determine if there are any potential parameter errors in the system.

Parameter error detection or identification is the process by which the measurement residuals are examined to determine if parameter errors exist. Parameter errors are detected by identifying residuals with high sensitivity to a common device parameter which may indicate that the parameter is in error in one embodiment. Two example approaches which may be utilized for parameter error detection and identification are discussed below and see also A. Abur and J. Zhu, “Identification of parameter errors,” Power and Energy Society General Meeting, 2010 IEEE. pp. 1-4, 2010, the teachings of which are incorporated herein by reference.

In the first example approach, a sensitivity matrix is utilized and the reader is additionally referred to A. Abur and A. Exposito, Power system state estimation: theory and implementation. 2004, the teachings of which are incorporated herein by reference. The sensitivity of the measurement residuals to measurement errors is referred to as the Sensitivity Matrix (S) as given by Equation (3.4) in one embodiment.

S=1−HG⁻¹H^{T}R⁻¹ (3.4)

From the sensitivity matrix, the covariance matrix is calculated as shown in Equation (3.5).

Ω=SR (3.5)

Elements of the covariance matrix indicate how strongly coupled measurements are. Additionally, the covariance matrix is used to normalize measurement residuals.

$${r}_{i}^{N} = \frac{{r}_{i}}{\sqrt{{Ω}_{ii}}} = \frac{{z}_{i} - {h}_{i}}{\sqrt{{Ω}_{ii}}} \qquad ( 3.6 )$$

Normalized residuals can be used for the detection of bad measurements where if they are above the threshold of 3.0, then the measurement is generally considered suspect. Additionally, normalized residuals can be used for the detection of bad parameters. If all of the normalized residuals of measurements sensitive to a particular parameter are high, an erroneous parameter value may be indicated. By using sets of high-valued normalized residuals it is possible to identify the specific equipment parameter that is causing the high residuals. For example, if there are a number of high residuals in reactive power, but not real power, this could be an indication that the assumed value of the capacitance parameter for an underground cable is inaccurate. Additional details are discussed below.

In the second example approach, an additional metric of Normalized Lagrangians are utilized to identify parameter error where the state estimation problem is augmented in a classic Lagrangian fashion and details of which are discussed in J. Zhu and A. Abur, “Identification of network parameter errors,” Power Systems, IEEE Transactions on, vol. 21, no. 2. pp. 586-592, 2006, the teachings of which are incorporated by reference herein. The parameters in the system, P, are defined as p=pt+∈, where pₜ is the true network parameter and ∈ is the parameter error. The measurement vector z will then be expressed as z=h(x,∈)+e, where z is the measurement vector, h is the nonlinear function relating the measurement vector to the state vector and network parameters, x is the system state vector, and e is the vector of measurement errors. The parameter error vector is taken to be zero and can appear as an equality constraint on the state estimation problem.

As before, the objective function J(x) may be minimized:

J(x)=[z−h(x)]^{T}R⁻¹[z−h(x)] (3.7)

but subject to the constraint:

∈=0 (3.8)

Forming the Lagrangian and applying first order optimality conditions leads to classic state estimation equations as well as an additional set:

$$\frac{\partial L}{\partial ɛ} = {H}_{s}^{T} {R}^{- 1} ( z - h ) + λ = 0 \qquad ( 3.9 )$$

### Where

$${H}_{ɛ}^{T} = \frac{\partial h ( x , ɛ )}{\partial ɛ}$$

and λ is the Lagrange multiplier for the parameter error constraint. λ can be expressed as shown in 3.10.

$$\begin{matrix}λ = - \frac{\partial {h ( x , ɛ )}^{T}}{\partial ɛ} {R}^{- 1} ( z - h ) \\ = - {H}_{ɛ}^{T} {R}^{- 1} ( z - h ) \\ = ψ ( z - h )\end{matrix} \qquad ( 3.10 )$$

A statistical test for detection of parameter errors based on λ can be developed. It is assumed that all Lagrange multipliers are distributed according to a normal distribution with zero mean and non-zero covariance. The covariance matrix can be derived following the relationship between the Lagrange multipliers and measurement residuals

Λ=cov(λ)=ψΩΨ^{T} (3.11)

Similarly to measurement residuals, the Lagrange multipliers can be normalized as

$${λ}_{i}^{N} = \frac{{λ}_{i}}{\sqrt{{Λ}_{ii}}} \qquad ( 3.12 )$$

A typical threshold of 3.0 can be used to identify suspect parameter values in one embodiment. Whether using a sensitivity matrix or normalized Lagrangians, suspect parameters may be identified from measured values. Both approaches for detecting parameter error may be applied to unbalanced distribution systems in the described embodiment.

The output of this step is a list of device parameters that are identified as outside of the expected values indicated by the planning model. It is possible that multiple parameter errors will be identified, and it will need to be determined if all identified values must be estimated, given the limits imposed by observability. Since AMI data used in one embodiment is generally recorded on 5-minute or 15-minute intervals, there is sufficient time to track numerous parameters. The effects that are being examined happen over long time frames, so computational burdens should be low.

As mentioned above, following identification, the identified parameters which are outside of their expected values, may be processed to determine if the values are constant or time-varying. Parameters errors (e.g., cable resistance, overhead line resistance, etc.) that are constant and parameter errors that are time-varying constitute two distinctly different scenarios. If a parameter error is identified, and it value is constant, but outside of the expected value, it must be determined if the source data is in error.

Distribution planning models have many potential sources of error and examples include, but are not limited to: errors from the import of the utility Graphical information System (GIS), incorrect line lengths in the database, incorrect conductor type in the database, and incorrect cable type in the database. In any of these cases, a constant value parameter error can indicate an error in the source data (e.g., distribution planning model).

One option is to conduct an analysis to determine the best fit value of the parameter, and to use this as the new value in the source data. If this is done, it should be noted and updated in the planning model that this substitution has been made. If the value is time-varying, the time-varying characteristics are tracked and compared to a model of expected behavior to see if the variation is within expected parameters, or an indication of a potential problem.

Two example methods of tracking parameter errors which may be utilized are discussed below. The first is a state augmentation based approach, and the second is an extension of the parameter error detection using the sensitivity matrix.

In the first method, the suspected parameters are included in the state vector and both the state and parameters are simultaneously estimated. Several snapshots, or sets of measurements taken at the same time step, are aggregated and used for a single step of the state estimation and parameter estimation process in order to increase the local redundancy around suspected parameters and increase the accuracy of estimates of parameter values. Except for some observability and numerical issues (e.g., risk of Jacobian singularity at flat start) this approach is an extension of the conventional state estimation model.

States are expressed as

x=[θ₂ . . . θₙV₁ . . . Vₙpₐᵣₐₘ]^{T} (3.13)

x′=[θ₂ . . . θₙV₁ . . . Vₙ]^{T}

pₐᵣₐₘ=p_{aram,1} . . . p_{aram,2} is the vector of estimated parameter values

h(x)=[Pᵢ^{p}Qᵢ^{p} . . . Vᵢ^{p} . . . ]^{T} (3.14)

For a full three phase model, a power injection measurement at bus i on phase p, Pᵢ^{p}, involves a double sum, taken over all buses and all phases in similar terms to (3.3).

$${P}_{i}^{p} = {V}_{i}^{p} {\sum }_{k = 1}^{n} {\sum }_{q = 1}^{3} {V}_{k}^{q} [ {G}_{ik}^{pq} cos {θ}_{ik}^{pq} + {B}_{ik}^{pq} sin {θ}_{ik}^{pq} ] \qquad ( 3.15 )$$

The corresponding measurement Jacobian:

$$H ( x ) = \frac{\partial h ( x )}{\partial x} \qquad ( 3.16 )$$

The Jacobian has two components as shown in Equation (3.17): one is the derivative of h with respect to states Equation (3.18), the other one is the derivative of h with respect to parameters Equation (3.19).

$$\begin{matrix}H ( x ) = [ \begin{matrix}H ( {x}^{′} ) & H ( {p}_{aram} )\end{matrix} ] & ( 3.17 ) \\ H ( {x}^{′} ) = [ \begin{matrix}\frac{\partial {h}_{1}}{\partial {θ}_{2 a}} & \frac{\partial {h}_{1}}{\partial {θ}_{2 b}} & \frac{\partial {h}_{1}}{\partial {θ}_{2 a}} & … & \frac{\partial {h}_{1}}{\partial {θ}_{na}} & \frac{\partial {h}_{1}}{\partial {θ}_{nb}} & \frac{\partial {h}_{1}}{\partial {θ}_{nc}} & \frac{\partial {h}_{1}}{\partial {V}_{1 a}} & \frac{\partial {h}_{1 }}{\partial {V}_{1 b}} & \frac{\partial {h}_{1}}{\partial {θ}_{1 c}} & … & \frac{\partial {h}_{1}}{\partial {V}_{na}} & \frac{\partial {h}_{1}}{\partial {V}_{nb}} & \frac{\partial {h}_{1}}{\partial {V}_{nc}} \\ \frac{\partial {h}_{2}}{\partial {θ}_{2 a}} & & & & & & & & & & & & & ⋮ \\ ⋮ & & & & & & & & & & & & & \\ \frac{\partial {h}_{m}}{\partial {θ}_{2 a}} & … & & & & & & & & & & & … & \frac{\partial {h}_{m}}{\partial {V}_{nc}}\end{matrix} ] & ( 3.18 ) \\ H ( {p}_{aram} ) = [ \begin{matrix}\frac{\partial h}{\partial {p}_{aram , 1}} & … & \frac{\partial h}{\partial {p}_{aram , n}}\end{matrix} ] = [ [ \begin{matrix}\frac{\partial {h}_{1}}{\partial {p}_{aram , 1}} \\ \frac{\partial {h}_{2}}{\partial {p}_{aram , 1}} \\ ⋮ \\ \frac{\partial {h}_{3}}{{p}_{aram , 1}}\end{matrix} ] … [ \begin{matrix}\frac{\partial {h}_{1}}{\partial {p}_{aram , 1}} \\ \frac{\partial {h}_{2}}{\partial {p}_{aram , 1}} \\ ⋮ \\ \frac{\partial {h}_{3}}{{p}_{aram , 1}}\end{matrix} ] ] & ( 3.19 )\end{matrix}$$

To perform a state estimation more frequently, and do the parameter estimation less frequently, a stacking method is used in one implementation. Multiple previous state estimation results are stacked into a large matrix to estimate a set of parameters. The Jacobi matrix Equation (3.17) is expanded as follows:

$${H}_{stack} ( {x}_{stack} ) = [ \begin{matrix}{H}_{1} ( {x}_{1 SE}^{′} ) & & & {H}_{p 1} ( {p}_{aram} ) \\ & … & & ⋮ \\ & & {H}_{w} ( {x}_{wSE}^{′} ) & {H}_{p w} ( {p}_{aram} )\end{matrix} ] \qquad ( 3.20 )$$

where w is the number of state estimations and also the width of a moving window. It's the same as other matrices: the state vector x, diagonal matrix of weighting values R, vector of measurement equations h, and vector of measurements z.

The moving time step is a time interval between two snapshots. At the completions of stacked state estimation there will be w sets of voltage state estimates and a set of single parameter estimates. Thus, the parameter estimate is the best fit for all time points stacked as input for the estimator.

The second example method of estimating parameter errors can be performed separately from state estimation in an external loop. After the state estimation is performed, the vector of measurement residuals, r, sensitivity matrix, S, and Jacobian with respect to parameters,

$$\frac{\partial h ( x , v )}{\partial v} ,$$

can be computed. The parameter error can be computed from these quantities in the following fashion.

The sensitivity matrix, S, calculated in Equation (3.4), also provides the relationship between residuals and measurement errors, r=Se. A linear relationship can be found between measurement residuals and parameter error using Equation (3.21).

$${τ}_{s} = ( {S}_{ss} \frac{\partial {h}_{s}}{\partial p} ) ɛ + \overline{{r}_{s}} \qquad ( 3.21 )$$

where Sₛₛ is the submatrix of S corresponding to s involved measurements and r̅ₛ is the residual that would have been found if the parameter were correct.

The relationship given in Equation 3.21 can be interpreted as a local estimation problem and the optimal value of c in the least squares sense can be computed using Equation 3.22.

$$ɛ = {[ {( \frac{\partial {h}_{s}}{\partial p} )}^{T} {R}_{s}^{- 1} {S}_{ss} ( \frac{\partial {h}_{s}}{\partial p} ) ]}^{- 1} {( \frac{\partial {h}_{s}}{\partial p} )}^{T} {R}_{s}^{- 1} {r}_{s} \qquad ( 3.22 )$$

The estimated error can then be used to update the parameter value in the system model.

If multiple sets of measurements are available (e.g., using AMI data), the parameter can be estimated more robustly by considering many measurement sets together. The measurement residual vectors can be concatenated, as can the S, R, and

$$\frac{\partial h}{\partial v}$$

computed at each solution of the state estimation process. The parameter error can be computed from these augmented inputs, either at each time step, using data from a moving window, or once per some multiple of measurement time steps.

Regardless of which of the two example methods is used, the output from the parameter estimation and tracking may be a plot showing the variation of a parameter(s) of interest over time as time-varying values.

As previously discussed, it is possible to use groups of high normalized residuals to identify what specific equipment parameter is in error in one embodiment. For example, if multiple real power injections are identified as parameter errors, but not reactive power injections or voltage magnitudes, the self-impedance of an overhead line, \hat{Z}ᵢᵢ, may be the cause. The self-impedance of an overhead line is given by Equation 3.2 and which is discussed in W. Kersting, “Radial distribution test feeders,” . . . Engineering Society Winter Meeting, 2001. IEEE, 2001, the teachings of which are incorporated herein by reference.

$${\hat{Z}}_{ii} = {r}_{i} + 0.9530 + j 0.12134 ( ln ( \frac{1}{{GMR}_{i}} + 7.79402 ) ) ohm / mile \qquad ( 3.23 )$$

where:

rᵢ: Resistance of the phase conductor

GMR: Geometric Mean Radius

If the self-impedance of a line, \hat{Z}ᵢᵢ, is identified as a time-varying parameter error, Equation 3.23 shows that the source of the variation tracks to the resistance, rᵢ, since rᵢ is the only value that is not a fixed geometric constant.

Assuming fixed geometric values for an underground cable is reasonable since the only way for them to change would result in mechanical damage to the cable which would result in catastrophic damage. Similar to the overhead line, if the capacitance of an underground cable is identified through parameter errors this can be correlated to a physical characteristic of the cable; specifically the insulation jacket. Equation (3.24) shows the correlation between the capacitance of a concentric neutral cable and the insulating jacket.

$${C}_{pg} = \frac{2 π {ɛ}_{0} {ɛ}_{r}}{ln ( {R}_{b} / {RD}_{c} ) - ( 1 / k ) ln ( {kRD}_{s} / {R}_{b} )} μ S / mile \qquad ( 3.24 )$$

where:

∈₀: Permittivity of free space

∈ᵣ: Permittivity of material (insulating jacket)

Once again similar to the overhead line, variations in the capacitance of the cable can be tracked directly to the permittivity of the insulating material, ∈_{T}. In both example cases, the variation of overhead line resistance and the dielectric properties of cable insulating jackets over time are understood and modeled. Comparing the values as tracked over time to what is expected based on known models will form the basis for determining if the distribution system elements/components need to be replaced.

In another example, the parameter of a component being tracked may be compared with the same parameter of other similar components (e.g., cable insulation resistances of cables). Typically, the parameters of similar components will vary similarly over time and a parameter of one component varying differently from the corresponding parameter of other similar components may be utilized to flag the one component as being of interest for further investigation.

In an example embodiment for monitoring components comprising cables, the lumped parameter of the line charging (i.e., capacitance to ground at each end of the cable) is tracked. As changes occur the cable will be flagged for review by the user.

A threshold may be used to determine if a tracked parameter of a component varies sufficiently from a model or other components to warrant further investigation of the component. Different thresholds may be used for different parameters and components in one embodiment.

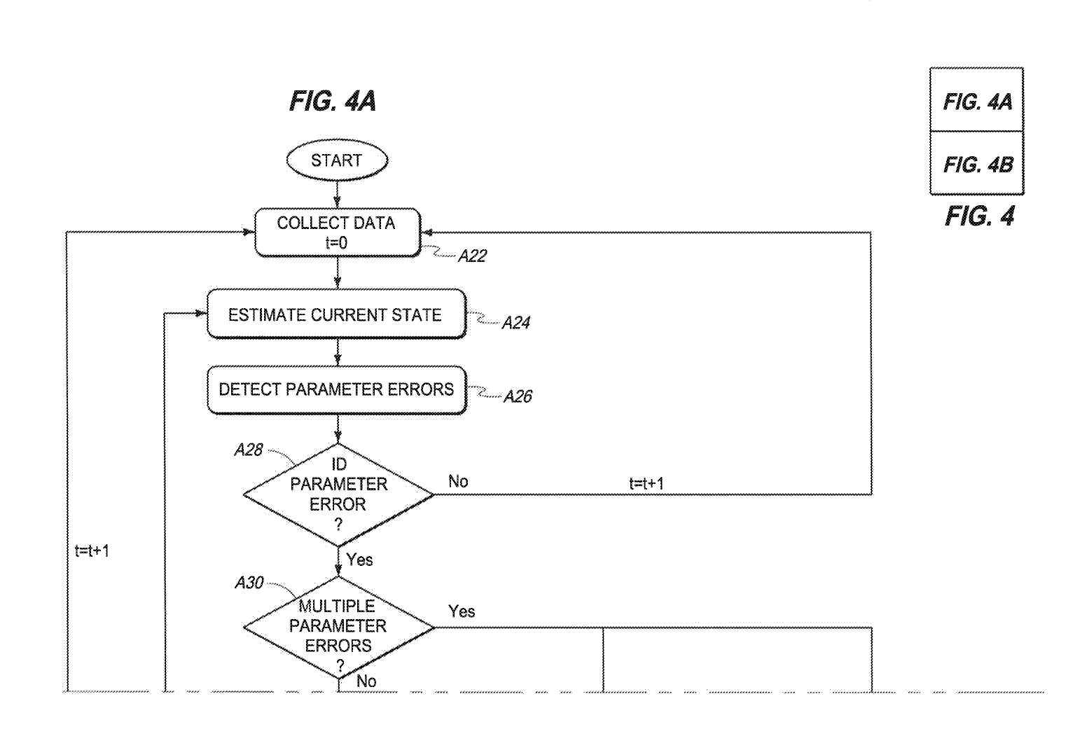

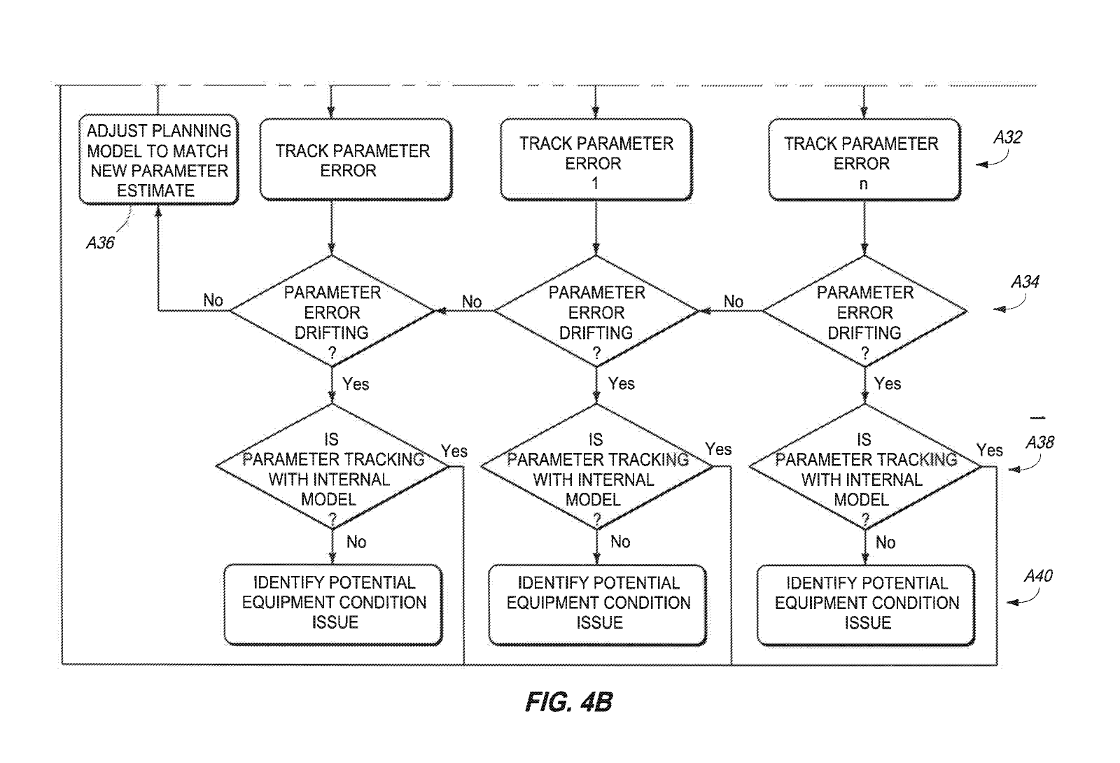

Referring to FIG. 4, one example method which may be executed by the computing system 20 implement processing and analysis operations with respect to the electrical power system 10 is shown in additional detail compared with the example of FIG. 3. Other methods are possible including more, less and/or alternative acts.

At an act A22, plan data, operational data, and electrical data of the electrical power system is accessed. In the illustrated iterative example, the first collection of data is at a time t=0.

At an act A24, the current state of the electrical power system is estimated. In one embodiment, three unbalanced single phase branches of the distribution network are estimated.

At an act A26, methods are executed to detect errors of parameters of components of the electrical power system.

At an act A28, it is determined whether any errors were detected.

If not, the method returns to act A22 to access additional data at a next time t=1.

If so, the method proceeds to an Act A30 to determine if parameter errors of multiple components were detected.

If no, acts A32, A34, A38, and A40 are executed with respect to the single parameter error and associated component.

If yes, acts A32, A34, A38, and A40 are executed with respect to the plurality of parameter errors and associated components.

At act A34, the parameter error(s) are tracked and it is determined whether one or more of the parameter error(s) are drifting or constant.

If constant, the method proceeds to an act A36 to adjust the plan data (e.g., planning model) to provide the value of the parameter with the new estimated value.

If drifting, the method proceeds to an Act A38 to determine whether the parameter is tracking with a known internal model for the parameter.

If yes, the method returns to act A22 to access additional data at a next time t=1.

If no, the method proceeds to act A40 to identify the respective parameter(s) as being in a potentially degraded state. For example, an output may include a list of transformers and underground cables that are flagged as having abnormal conditions which may warrant additional investigation, potential inspection, repair, or replacement.

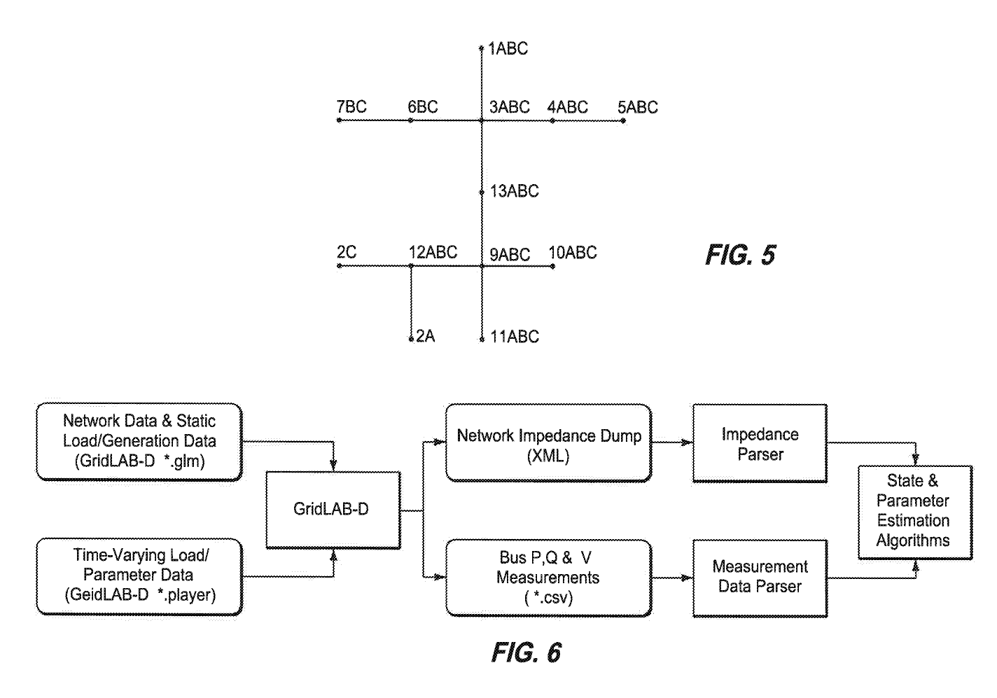

The process described above has been applied to a modified IEEE test system and results of state estimation processing upon a model system are described below. The model system was a modified version of the IEEE 13 Node Test Feeder. Simplifications were made to the original IEEE test feeder to focus the simulations on the core interest of state and parameter estimation. A switch was collapsed, the regulator and transformer were not modeled, and a delta load was transformed into a Y load. The schematic of the distribution feeder used in the simulations described in this section are shown in FIG. 5 where node numbers and phases are labeled. An individual dot of FIG. 5 corresponds to a bus and the particular phases (and associated nodes) coupled with each bus, i.e., A, B, and C.

In order to streamline the process of preparing input data for the state estimation and parameter estimation procedures, as well as to facilitate the generation of multiple measurements/time steps, the test feeder was constructed in an input format for GridLAB-D. Whether for a single time step or a one-year set of data, GridLAB-D was used to create perfect (no noise) measurement sets with real power injection, reactive power injection, and voltage magnitude for every bus at every time step. GridLAB-D was also configured to output a data structure containing the network impedance data in a form acceptable for the state and parameter estimation procedures. This data structure included primitive three-phase impedance matrices for each link in the system. Supplementary scripts were written to parse the measurement data and add noise/error where appropriate, as well as to construct a formal three-phase admittance matrix from the primitive impedance data. This process of GridLAB-D data collection and processing flow is outlined in FIG. 6.

Using the above-described methods, a state estimation was performed using simulated measurements generated by GridLAB-D. There are a wide variety of ways to evaluate the performance of a state estimator. One common way is to compare the estimated values of the state vector to the true values, which can be computed when there is perfect knowledge of the system, as in a simulation experiment. For a system with N voltage magnitude elements in the state vector, define the average absolute value in the estimation to be

$${S}_{\vert V \vert} = \frac{1}{N} {\sum }_{i = 1}^{N} \vert {V}_{t} - {V}_{est} \vert \qquad ( 4.1 )$$

where Vₜ is the true value of the voltage magnitude as solved by power flow, and Vₑₛₜ is the voltage magnitude estimated by the state estimator. Similarly, for voltage angle,

$${S}_{θ} = \frac{1}{N} {\sum }_{i = 1}^{N} \vert {θ}_{t} - {θ}_{est} \vert \qquad ( 4.2 )$$

If no simulated measurement error is induced, the per-unit S_{|V|} is less than 5×10⁶ and the value of Sₑ is less than 2×10⁶. These values are at the limit of accuracy given the precision of the simulated measurements, proving the successful operation of the three phase state estimator.

The above-described parameter error detection methods were tested by taking the system data generated by GridLAB-D and introducing an erroneous value. The parameter ‘R1-3aa’ refers to the real part of the direct a-phase element of the 3×3 impedance matrix that describes the characteristics of the line linking node 1 and node 3. That parameter was set to several erroneous values, and the above-described parameter error detection methods were applied to detect the error. Below the normalized measurement residuals and normalized Lagrangian are plotted as a function of fractional parameter error. In this case, R1-3aa was set to a variety of erroneous values and then the parameter error detection algorithms were carried out after the state estimation had completed.

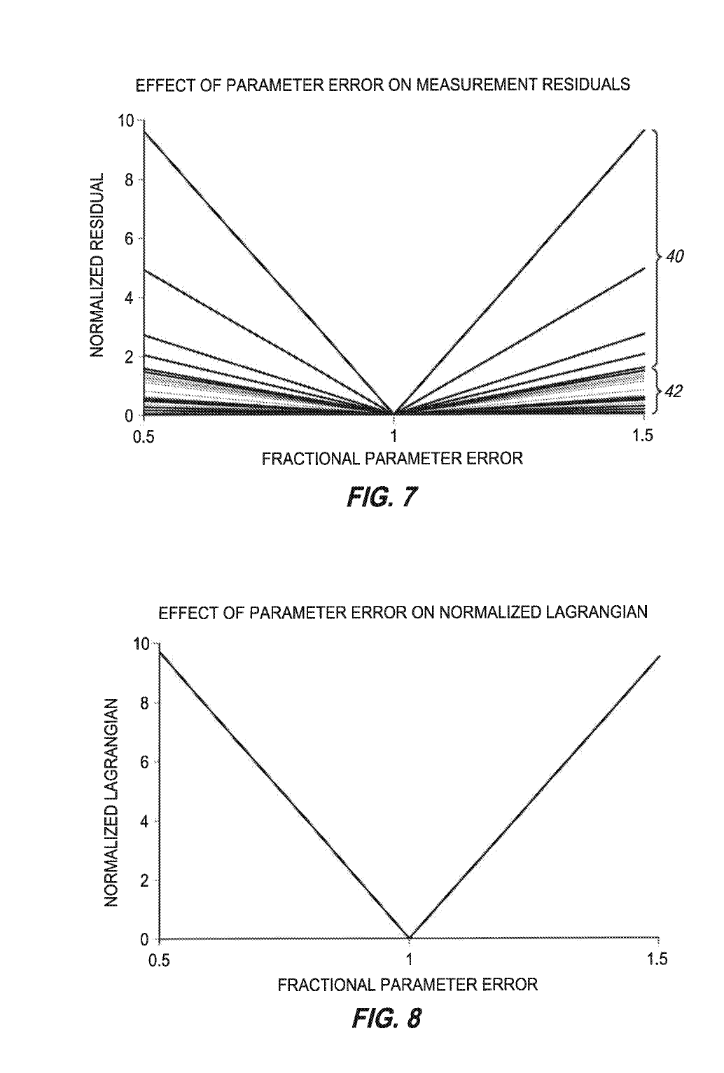

FIG. 7 illustrates the effect of error induced on parameter R1-3aa on normalized measurement residuals. Lines 40 represent measurements on nodes 1 or 3 and lines 42 represent measurements on other nodes.

FIG. 8 illustrates an effect of error induced on parameter R1-3aa on normalized Lagrangian. As can be seen in FIGS. 7 and 8, an induced parameter error of 15% is sufficient to raise either the measurement residuals or the normalized Lagrangian above the detection threshold of 3.0 in one example. The normalized Lagrangians are made up of linear combinations of measurement residuals, scaled by the strength of influence that a given parameter has on a measurement. In this particular case, the normalized Lagrangian displays a similar degree of sensitivity to parameter error as the most sensitive normalized measurement residual, but that is not true in all cases.

The normalized Lagrangian method has the additional advantage that multiple state estimations can be performed at successive points in time, and then the outputs of each can be concatenated to calculate a single normalized Lagrangian, increasing the sensitivity.

The value of an unknown or erroneous parameter was estimated for multiple test cases using both of the techniques described above for parameter estimation and tracking. The cases are of the types static and time varying. The static cases are used to exemplify some of the details that are not visible when multiple time points are plotted. The analysis of results from time varying cases is focused on the ability to track parameter changes through time.

To examine the ability to detect changes in line charging capacitance, an exponentially growing shunt capacitance was added to the model at node 13. The expectation is that this parameter will change as an underground cable reaches end of life. The system data that was used for state estimation contained a small and constant shunt capacitance, and the exponentially growing shunt capacitance could be detected and estimated by both methods shown below.

The parameter error estimation technique described above for parameter estimation/tracking with augmenting the state vector was deployed and implemented. Case studies are carried out to test the methodology of parameter estimation, which are: Single parameter and single snapshot, Multiple parameters and two snapshots, Single parameter and time series snapshots with no growth of shunt capacitance, and Time series snapshots with exponential growth of shunt capacitance.

### Single Parameter and Single Snapshot

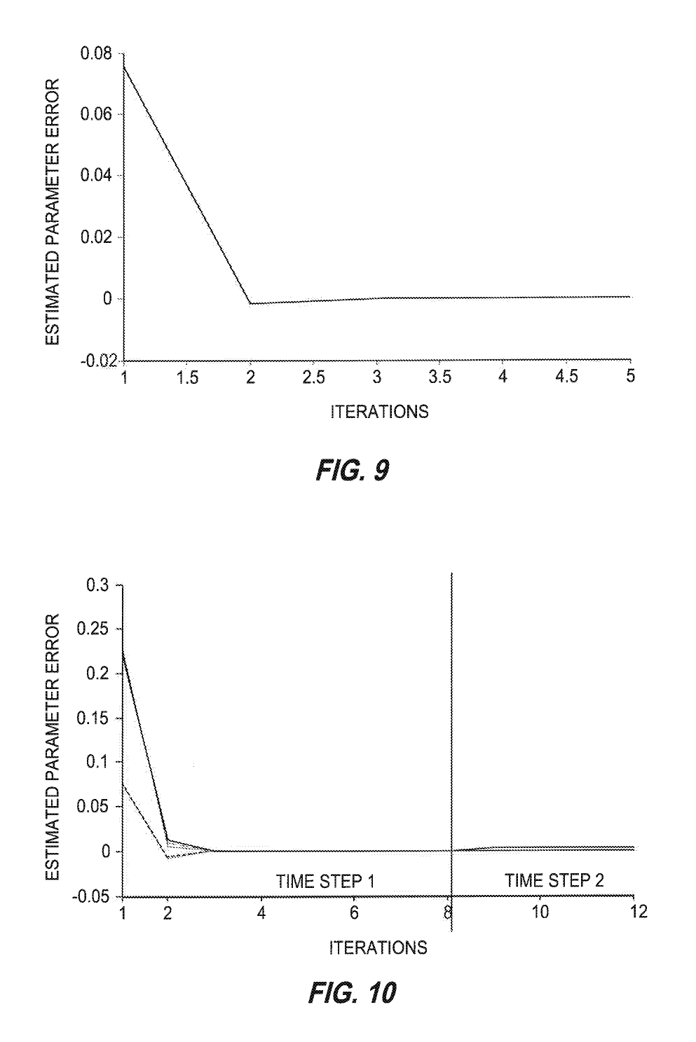

In this case, R1-3aa, a critical resistance on an upstream line (link 1-3, phase a-phase a), is estimated individually and the estimated parameter values change with iterations, which is presented in FIG. 9 showing estimated error on parameter R1-3aa at one snapshot. The initial value we set to use a doubled value of the true value of R1-3aa (i.e. the initial value is 0.1518 p.u.). The true value is 0.0759 p.u. So the error was 0.0759 initially. After 4 iterations, the estimated error, the difference between the estimated value and the true value, merged to zero.

### Multiple Parameters and Two Snapshots

It requires 8 iterations to converge for estimating 6 parameters simultaneously. Afterwards, it reads the second snapshot as a new measurement data set with a step change in the R1-3aa. The estimated value of R1-3aa converged to a new value (which is the new true value). In FIG. 10 showing estimated error on multi-parameters (R1-3aa, X1-3aa, R1-3bb, R1-3bb, R1-3cc, and X1-3cc) at two snapshots, there is a step change in the estimate error, which is a differential from the original true value. The difference can be observed after the 9th iteration. This method can estimate step change on R1-3aa.

Single Parameter and Time Series Snapshots with No Growth of Shunt Capacitance

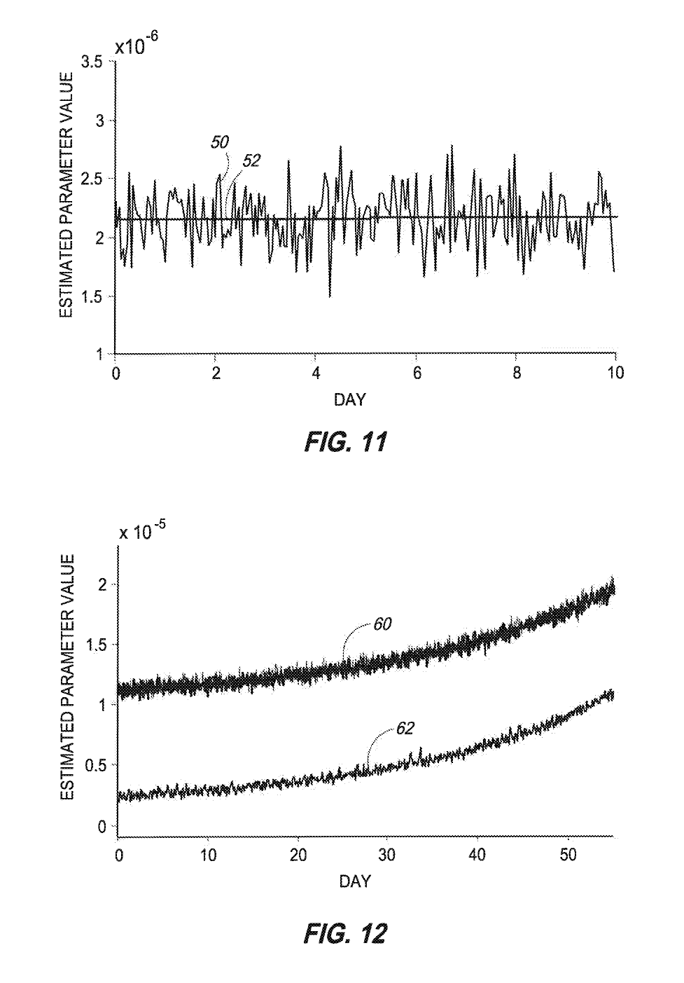

In this case, there is no growth of shunt capacitance at node 13. B13-9aa is estimated based on hourly time series measurement data set. All system parameters remain constant while the measurement data changes with time increasing. FIG. 11 shows estimated error 50 on parameter B13-9aa at one snapshot indicating there are many noises in the estimated values. A linear fitting 52, which removes the oscillations of the estimated values, is also shown.

Time Series Snapshots with Exponential Growth of Shunt Capacitance

Based on the time series snapshots with exponential growth of shunt capacitance at node 13, parameter B13-9aa, B13-9bb, and B13-9cc are estimated simultaneously, shown in FIG. 12. Line 62 represents parameter B13-9aa while line 62 represents parameters B13-9bb and B13-9cc It can be observed the estimated parameter values increased significantly within the 54 days.

Next, a stacking method was used, for example the above-described parameter tracking method with augmenting the state vector. The solutions of the 24 (i.e. 1 day of hourly snapshots) previous state estimation results are stacked into a large matrix to estimate a set of parameters. The size of Jacobi matrix, states, and measurements matrices are expanded. With previous 24 times state estimations input, the parameters are estimated at each snapshot. In other words, 24 hours is the width of a moving window and the moving time step is one hour. States are estimated hourly for 24 hours and parameters are estimated at the end of these 24 hours. Each parameter estimation process requires 24 times previous state estimation.

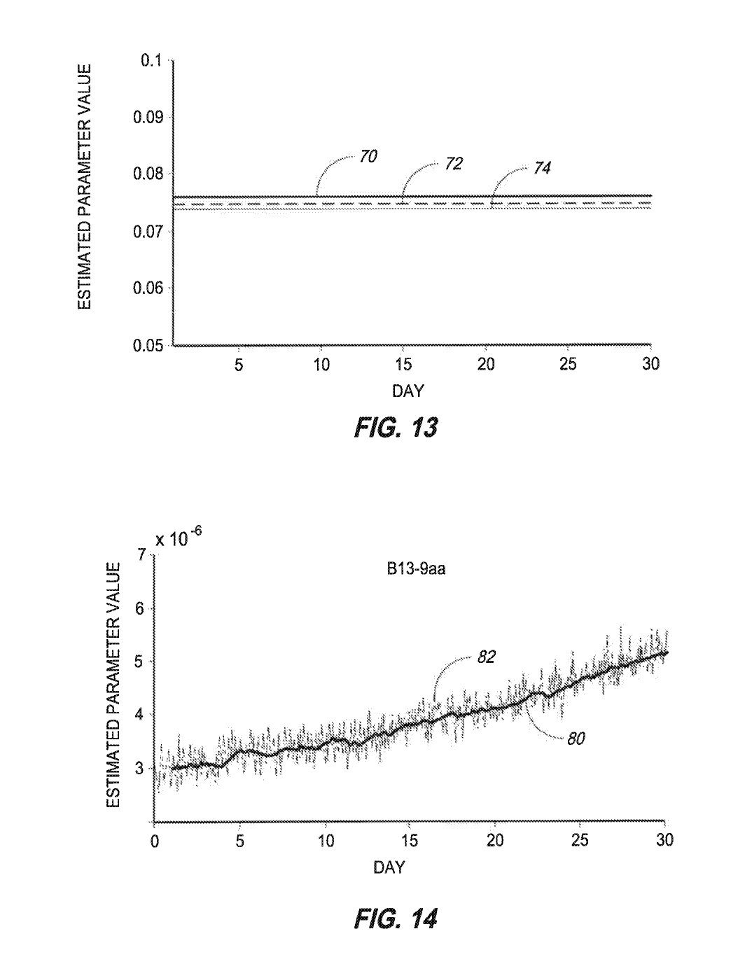

The true values of R1-3aa R1-3bb and R1-3cc are 0.07585, 0.07386, and 0.074720. Using the state augmenting and the stacking method, the errors on parameters R1-3aa R1-3bb and R1-3cc are correctly estimated simultaneously and remain constant for 30 days as shown in FIG. 13 where line 70 represents R1-3aa, line 72 represents R1-3cc and line 74 represents line R1-3bb.

A comparison of two results of B13-9aa parameter estimation with and without a stacking window is shown in FIG. 14. The stacking method shown by line 80 smooths the noises of the estimated values of B13-9aa compared with line 82 representing no-stacking, and both of results present the exponential growth as time increases.

FIGS. 13 and 14 show that this parameter estimation method can detect increase in shunt capacitance B13-9aa without taking R1-3aa, R1-3bb and R1-3cc as suspects. They indicate that parameter estimation can provide early warnings to system operators before they observe abnormal values from the raw measurement values.

The above-described parameter error estimation techniques were applied to two test cases. The cases included linear changes in series resistivity and exponential growth in shunt capacitance. The exponential shunt model case is the data set used with respect to FIGS. 11 and 12.

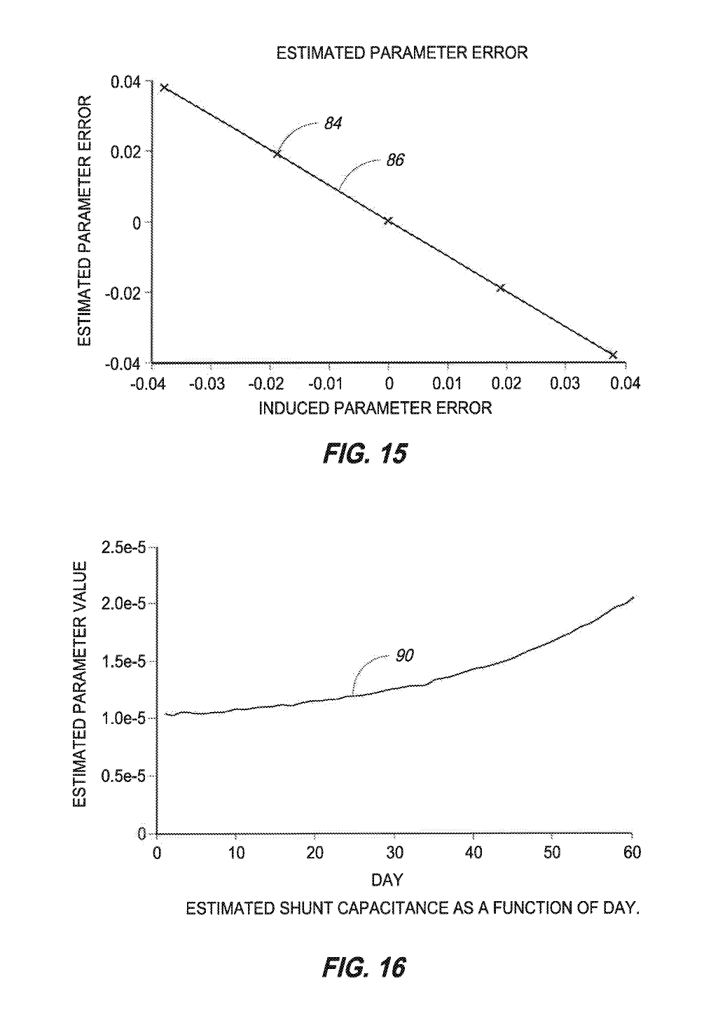

In the first case, error is induced in the parameter R1-3aa, and as previously discussed, the parameter error is then estimated using residual sensitivity analysis. The estimated parameter value is plotted on top of the induced parameter error in FIG. 15, showing excellent agreement. In this test system, the estimation for line resistance and reactance parameters is quite good.

Because the residual sensitivity analysis method of estimating parameter errors is based on a linear approximation, the method works better for small errors, and begins to break down when parameter errors are large enough to cause serious error in the state estimation process. Additionally, since parameter errors are estimated one at a time, based on the state estimation results, in a non-iterative fashion, an error in one parameter can sometimes affect estimate of error in a very closely related parameter.

In an additional test case, particularly relevant for the case of underground cable failure, an exponentially growing shunt capacitance was added to the model at node 13. The system data that was used for state estimation contained a small and constant shunt capacitance, and the exponentially growing shunt capacitance was able to be detected and estimated.

The shunt capacitance in a typical system will be small on the scale of other parameters in the system. In the per-unit system used in these calculations, the shunt capacitance values are on the order 10⁻⁶, whereas line resistance and reactance are on the order 10⁻¹. This extremely small value makes accurate estimation difficult, and it can be seen that at the very beginning of the simulation, there is not good agreement because the actual and estimated value.

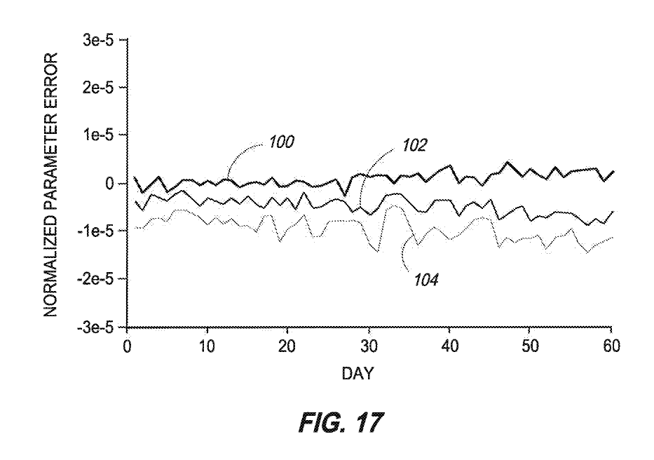

In FIG. 16, the estimated value of the shunt capacitance is represented by line 90 and was 1×10⁻⁶ at day 0 and 1×10⁻⁵ at day 53. In spite of the inaccuracy of the estimated value, the exponential growth trend is still clearly evident. The plotted parameter estimate was computed by taking a day of simulated AMI measurements, or 48 snapshots in time, and combining the results of each snapshot's state estimation for a single parameter estimation. FIG. 17 shows estimated error of line resistivity parameters of the 3-13 link where respective lines 100, 102, 104 represent R3-13aa, R3-13bb, R3-13cc. The same method applied to closely related parameters, the line resistivity on a link connecting to node 13, shows the expected null result. When the shunt capacitance was increased, the estimate of error on line resistivity remains near zero.

In one embodiment, electrical data in the form of AMI measurement data that is already being collected by existing infrastructure of utilities may be utilized. In some example applications of methods and apparatus of the disclosure, tracked equipment parameters may be integrated into a larger asset management system that may allow utilities to determine when/if proactive replacement of equipment is warranted. In some applications, the disclosed methods and apparatus may increase reliability by reducing unplanned outages, and reduce costs by only replacing equipment when appropriate. In addition, as more smart devices (i.e. switches, shunts, and regulators) are installed, there will be increased telemetry on the branch power flows of the feeders which will improve the state estimation and parameter estimation performed, and therefore the identification of degrading transformers and underground cables.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended aspects appropriately interpreted in accordance with the doctrine of equivalents.

Further, aspects herein have been presented for guidance in construction and/or operation of illustrative embodiments of the disclosure. Applicant(s) hereof consider these described illustrative embodiments to also include, disclose and describe further inventive aspects in addition to those explicitly disclosed. For example, the additional inventive aspects may include less, more and/or alternative features than those described in the illustrative embodiments. In more specific examples, Applicants consider the disclosure to include, disclose and describe methods which include less, more and/or alternative steps than those methods explicitly disclosed as well as apparatus which includes less, more and/or alternative structure than the explicitly disclosed structure.

What is claimed is:

1. An electrical power grid monitoring apparatus comprising:
a communications interface configured to access electrical data indicative of electrical energy received at a plurality of consumer locations from an electrical power grid at a plurality of moments in time, the consumer locations being coupled with one or more unbalanced single phase feeders of a distribution system of an electrical power grid and which individually comprise a plurality of components configured to conduct the electrical energy from at least one electrical energy source to the consumer locations; and
processing circuitry coupled with the communications interface and configured to use the electrical data to estimate a state of the electrical power grid and to identify one of the components as being in a potentially degraded state using the estimation of the state of the electrical power grid.

2. The apparatus of claim 1 wherein the electrical data comprises values of a characteristic of the electrical energy received at the consumer locations, and the estimation of the state of the electrical power grid provides values of the characteristic at a plurality of additional nodes of the electrical power grid in addition to the consumer locations.

3. The apparatus of claim 2 wherein the values of the characteristic are measured at the consumer locations.

4. The apparatus of claim 2 wherein the estimation of the state includes a plurality of residuals corresponding to differences between the values of the characteristic of the electrical energy received at the consumer locations and estimated values of the characteristic of the electrical energy received at the consumer locations, and the processing circuitry is configured to use the residuals to identify a parameter of the one component as being potentially erroneous.

5. The apparatus of claim 4 wherein the processing circuitry is configured to monitor the parameter of the one component as a result of the identification, and to identify the one component as being in the potentially degraded state as a result of the monitoring.

6. The apparatus of claim 5 wherein the processing circuitry is configured to indicate that one component is in the potentially degraded state as a result of varying of the parameter of the one component deviating from expected varying of the parameter over time.

7. An article of manufacture comprising:
computer-readable media storing programming configured to cause processing circuitry to perform processing comprising:
accessing a plurality of values of a characteristic of the electrical energy at a plurality of nodes of an electrical power grid which comprises a plurality of components individually configured to conduct electrical energy;
estimating a state of electrical power grid comprising estimating a plurality of values of the characteristic of the electrical energy at the nodes of the electrical power grid;
identifying a plurality of residuals corresponding to differences between the accessed and estimated values of the characteristic for respective ones of the nodes;
using the residuals, identifying one of the parameters of one of the components as potentially including error;
as a result of the identifying the one parameter, monitoring the one parameter; and
using the monitoring, determining the one component as being in a potentially degraded state.

8. The article of claim 7 wherein the monitoring comprises, after the identifying the one parameter, comparing varying of the one parameter over time with expected varying of the one parameter, and the determining the one component comprises determining as a result of the varying of the one parameter deviating from expected varying of the parameter over time.

9. The article of claim 7 wherein the power grid comprises a plurality of unbalanced distribution lines which include at least some of the nodes and the one component conducts the electrical energy within one of the unbalanced distribution lines.

10. The article of claim 7 wherein the estimating the state comprises estimating using a plurality of values of a characteristic of the electrical energy received at some of the nodes corresponding to a plurality of different consumer locations, and the estimating provides estimated values of the characteristic of electrical energy at others of the nodes in addition to the some nodes.

11. The article of claim 7 wherein the accessing comprises accessing measured values of the characteristic of the electrical energy at some of the nodes corresponding to consumer locations where electrical energy is received from the electrical power grid at a plurality of common moments in time, and the identifying comprises determining differences of the measured values with the estimated values for respective ones of the characteristics.

12. An electrical power grid equipment monitoring method comprising:
accessing plan data regarding a plurality of components configured to conduct electrical energy within an electrical power grid;
accessing operational data regarding the components of the electrical power grid, wherein the operational data comprises status information regarding the components;
accessing electrical data regarding electrical energy conducted within the electrical power grid; and
processing the plan data, the operational data and the electrical data to identify one of the components as being in a potentially degraded state.

13. The method of claim 12 wherein the electrical data comprises measurements of a characteristic of the electrical energy at a plurality of nodes of the electrical power grid at a plurality of moments in time.

14. The method of claim 12 wherein the processing comprises:
estimating a state of the electrical power grid including estimating values for a common characteristic of the electrical energy at a plurality of nodes of the electrical power grid;
using the estimated values and a plurality of measured values of the electrical data, determining a plurality of residuals;
using the residuals, identifying a parameter of the one component as potentially having error;
monitoring the parameter after the identifying the parameter; and
using the monitoring, identifying the one component as being in the potentially degraded state.

15. The method of claim 14 wherein the monitoring comprises, after the identifying the parameter, comparing varying of the parameter over time with expected varying of the parameter, and the identifying the one component comprises identifying as a result of the varying of the parameter deviating from expected varying of the parameter over time.

16. The method of claim 14 wherein the electrical data comprises measured data regarding the characteristic of the electrical energy received at a plurality of consumer locations which correspond to some of the nodes at a plurality of different common moments in time.

17. The method of claim 14 wherein the measured values comprise measured data regarding the characteristic of the electrical energy received at a plurality of consumer locations which correspond to some of the nodes, and wherein the determining the residuals comprises determining differences of the estimated values and the measured values at respective ones of the consumer locations.

18. The method of claim 16 wherein the estimating the state of the electrical power grid provides estimated values of the characteristic of the electrical energy at a plurality of different nodes of the electrical power grid in addition to the consumer locations.

19. The method of claim 12 wherein the identifying comprises identifying a plurality of the residuals having an increased sensitivity to the one parameter.

20. The method of claim 12 wherein the electrical power grid comprises a plurality of unbalanced distribution lines and the one of the components conducts the electrical energy within one of the unbalanced distribution lines.

21. The method of claim 14 further comprising identifying another of the parameters of another component as potentially having error; monitoring the another parameter over time; and updating the plan data using an estimated value of the another parameter as a result of the another parameter not sufficiently varying.
